(19) United States
(12) Patent Application Publication
(10) Pub. No.: US 2007/0076512 A1
(43) Pub. Date: Apr. 5, 2007

(54) Three transistor wordline decoder

(76) Inventors: Hernan A. Castro, Shingle Springs, CA (US); Alec Smidt, Folsom, CA (US); Johnny Javanifard, Carmichael, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/241,324

(22) Filed: Sep. 30, 2005

(51) Int. Cl. G11C 8/00

(52) U.S. Cl. 365/230.06

(57) ABSTRACT

A word line decode circuit may include three devices, a first p-type transistor, a first n-type transistor and a second n-type transistor together with a shared (with other word line decoding circuits) p-type transistor make up a “distributed” NOR gate. The first p-type transistor and the first n-type transistor may be toggled via the lowest level decode signal. To select a wordline, this low level decode signal may be low as well as a signal provided to the gate of the shared p-type transistor. The signal to the gate of the shared p-type transistor may be an output of a ratioed logic level shifter.

### TECHNICAL FIELD

Embodiments of the invention relate to memory circuits. More particularly, embodiments of the invention relate to a circuit having three transistors to determine whether an associated wordline has been selected.

### BACKGROUND

In general, reading and writing data to locations in physical memory devices include translation of a corresponding address into row and column coordinates within the memory devices. The use and general techniques of row and column decoding are well known in the art. For example, FIG. 1 illustrates portions of a memory device having four-transistor word line decoding circuits. The word line decoding circuitry generally includes four transistors that perform the function of a logical AND.

Transistor stack 190 operates as a selection signal and provides current to drive a selected word line (e.g., 155, 185). Row signal decoding circuitry (not shown in FIG. 1) is used to generate row decode signals 110. Signal 120 is a switched biased current control signal that is asserted to enable a portion of a memory device. The four transistors of the word line decoder circuit (e.g., 150, 180) operate to decode address signals to the memory and assert the respective word lines (e.g., 155, 185).

FIG. 2a illustrates an alternative illustration of the four word line decode transistors. Transistors 210, 220, 230 and 240 form logical AND gate that may be used to decode address signals (not illustrated in FIG. 2a) input to a memory device. Pull down transistors 250 have gates coupled to the address signals and may provide a path to ground. In typical prior art embodiments each of the four transistors is replicated for each word line. For example, in a block of memory having 16 word lines, the word line decoders would include 64 transistors (32 p-type and 32 n-type) in addition to pull down transistors 250 and any additional supporting circuitry. FIG. 2b illustrates a logic gate level illustration of the four word line decode transistors. For example, NAND gate 270 and inverter 280 may provide an equivalent function as the transistors of FIG. 2a.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is one embodiment of a prior art circuit for word line decoding.

FIGS. 2a and 2b are logically equivalent circuits of the word line decoder of FIG. 1.

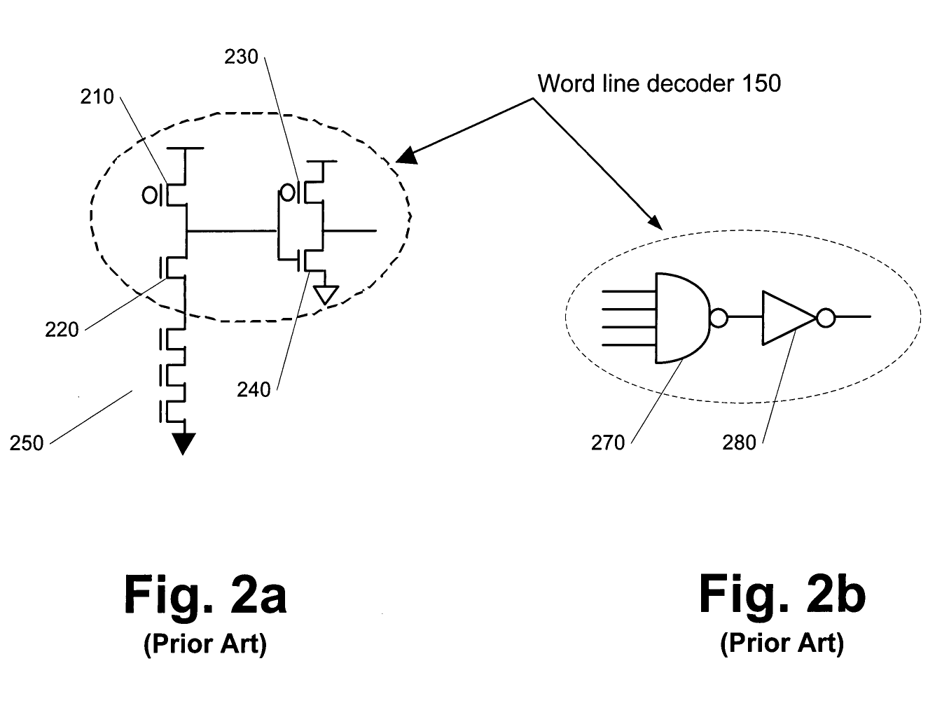

FIG. 3 is a circuit diagram of one embodiment of a word line decoding circuit having a distributed NOR functionality.

FIGS. 4a and 4b are logically equivalent circuits of the word line decoder of FIG. 3.

FIG. 5 is a block diagram of one embodiment of an electronic system having a wireless network interface and a memory device the may include a word line decoder as described herein.

### DETAILED DESCRIPTION

In the following description, numerous specific details are set forth. However, embodiments of the invention may be practiced without these specific details. In other instances, well-known circuits, structures and techniques have not been shown in detail in order not to obscure the understanding of this description.

In one embodiment a word line decode circuit may include three devices, a first p-type transistor, a first n-type transistor and a second n-type transistor together with a shared (with other word line decoding circuits) p-type transistor make up a “distributed” NOR gate. In one embodiment, the first p-type transistor and the first n-type transistor may be toggled via the lowest level decode signal. To select a wordline, this low level decode signal may be low as well as a signal provided to the gate of the shared p-type transistor. In one embodiment, the signal to the gate of the shared p-type transistor may be an output of a ratioed logic level shifter.

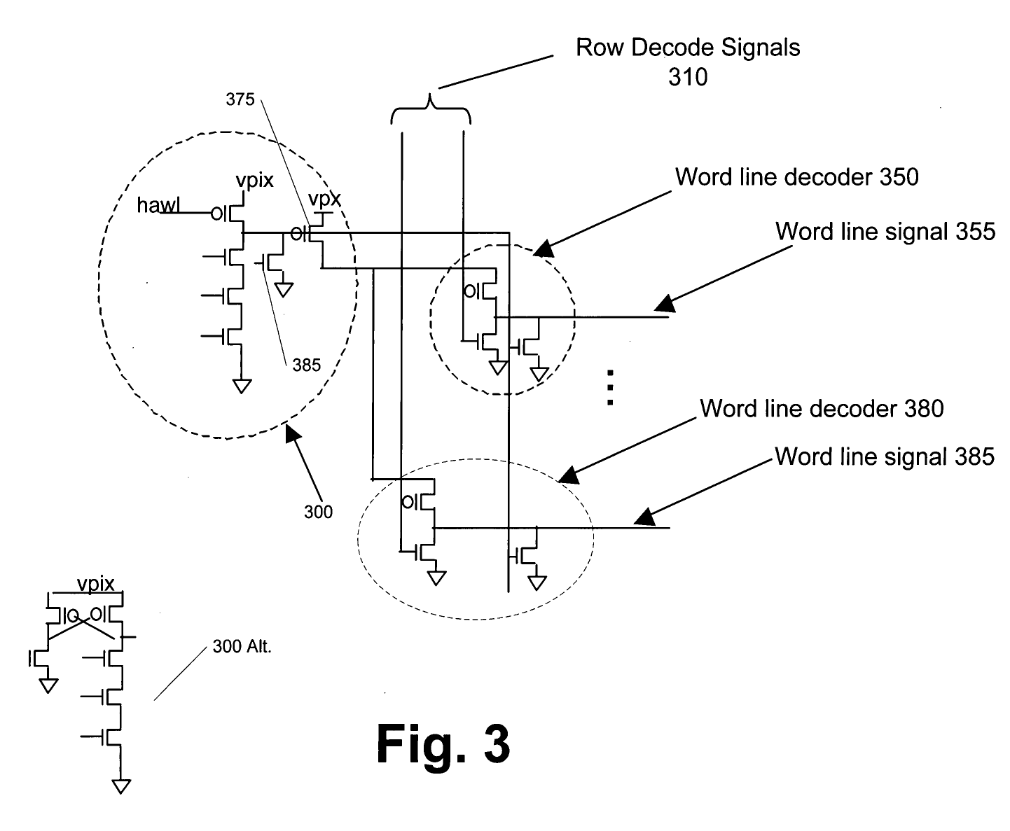

FIG. 3 is a circuit diagram of one embodiment of a word line decoding circuit having a distributed NOR finctionality. In one embodiment, each word line signal (e.g., 335, 385) may be asserted by a respective output node of a distributed NOR gate. Typically, a NOR gate includes four transistors configured as two p-type transistors in series coupled with two n-type transistors in parallel. In one embodiment, one or more of the transistors illustrated in FIG. 3 may be triple-well transistors.

In the word line decode circuit of FIG. 3, one of the two p-type transistors (375) of a NOR gate is shared between the word line decoders (e.g., 350, 380). In one embodiment, transistor 375 may be sized differently than the remaining transistors of the distributed NOR gate. In one embodiment, row decode signals 310 may be coupled with gates of transistors in the respective word line decode circuits.

The group of transistors labeled 300 (including the shared p-type transistor) may be shared among any number of word line decode circuits. In one embodiment, the shared NOR word line decode configuration may be used to decode input signals to assert one of 16 word lines. In alternate embodiments, a different number of word lines may be supported, for example, 2, 4, 8, 32, 64, etc. In one embodiment, the series connected p-type and multiple n-type transistors (of the transistor group 300) may be coupled to receive pre-decode signals at the respective gates. The p-type transistor of the stack may be a single ratioed transistor that may replace multiple p-type transistors in a corresponding fully complementary embodiment.

In one embodiment, transistors 300 may include an optional n-type pull-down device 385 that may be used for test purposes. The group of transistors labeled “300 Alt.” Illustrate an alternative embodiment for transistors 300. Other configurations may also be used. In one embodiment, the signal provided to the gate of shared transistor 375 may also be provided to the gate of one of the parallel n-type transistors in each of the word line decode circuits.

In the example circuit of FIG. 3, VPX, VPIX and ground are supply voltage levels that may change depending on, for example, the mode of operation (e.g., read, program, erase test) of the memory device. VPX and VPIX may be positive or negative supply voltages. Also ground may not be 0 volts under all conditions.

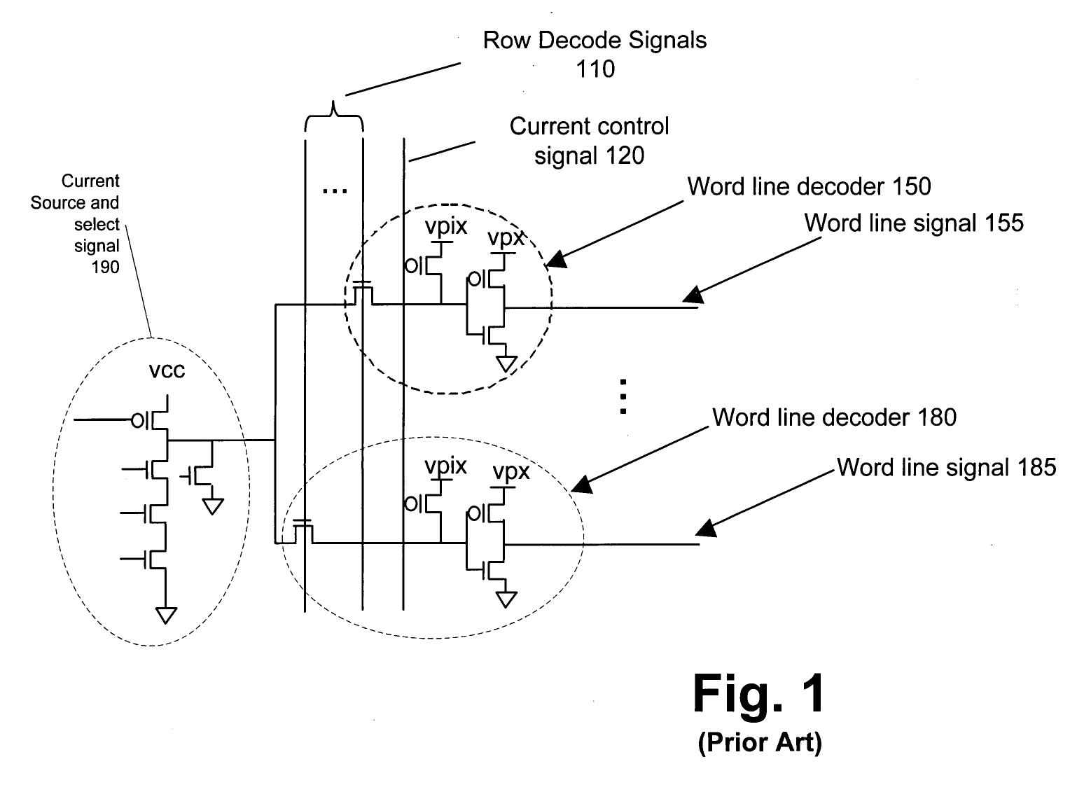

In the distributed NOR embodiment illustrated in FIG. 3, the number of transistors used for word line decoding may be reduced as compared to the four-transistor configuration illustrated in FIG. 1. For example, in a block of memory having 16 word lines, the word line decoders would include 49 transistors (the shared p-type transistor plus 16 p-type and 32 n-type transistors) in addition to pull down transistors 300 and any additional supporting circuitry. By requiring fewer transistors, the die area required for word line decoding may be reduced using a distributed NOR decoding technique.

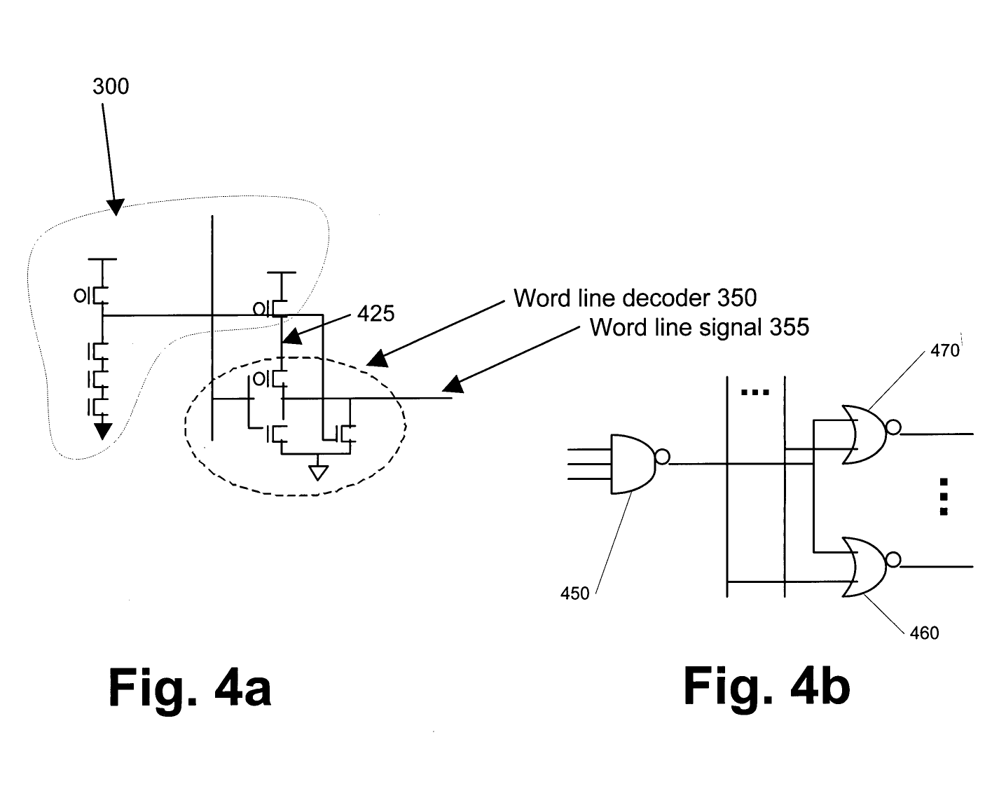

FIGS. 4a and 4b are logically equivalent circuits of the word line decoder of FIG. 3. In FIG. 4a, transistors 300 may be shared for decoding any number of word line signals. The three-transistor word line decoder (e.g., 350) to complete the NOR functionality may be replicated for each word line signal supported (e.g., 355). FIG. 4b illustrates a logically equivalent word line decoding configuration at the logic gate level. However, because FIG. 4b is not at the transistor level, the shared p-type transistor with consequent transistor count savings is not explicitly illustrated.

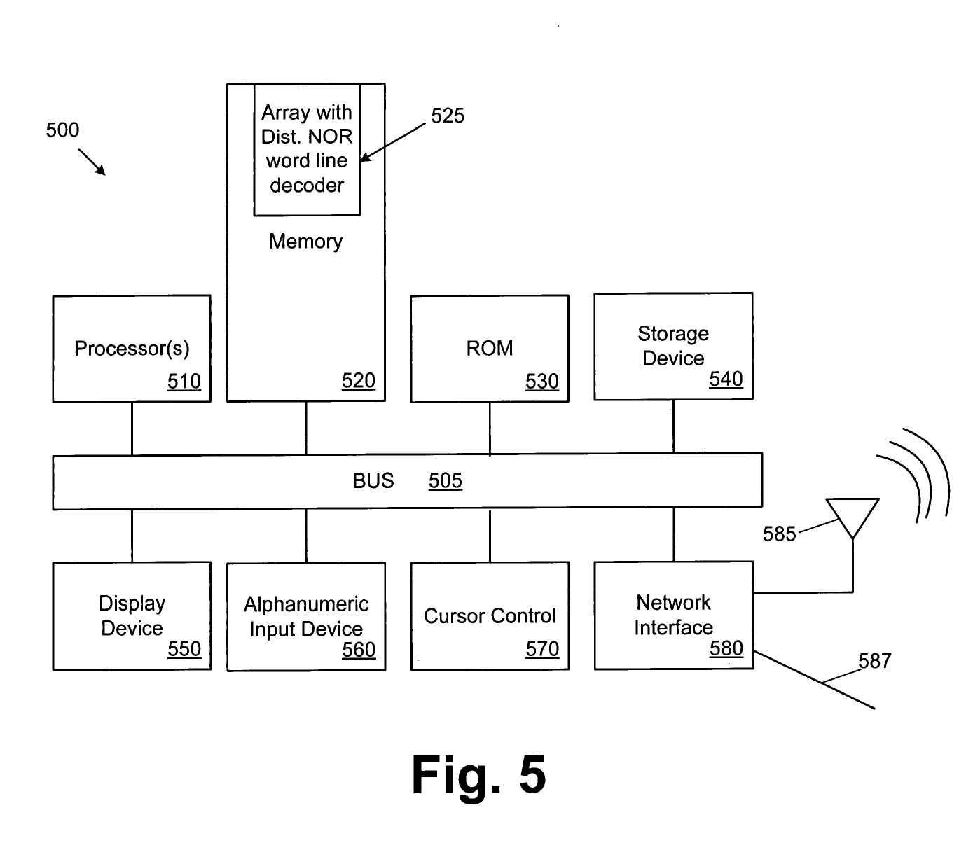

FIG. 5 is a block diagram of one embodiment of an electronic system having a wireless network interface and a memory device the may include a word line decoder as described herein. The electronic system illustrated in FIG. 5 is intended to represent a range of electronic systems (either wired or wireless) including, for example, desktop computer systems, laptop computer systems, cellular telephones, personal digital assistants (PDAs) including cellular-enabled PDAs, set top boxes. Alternative electronic systems may include more, fewer and/or different components.

Electronic system 500 may include bus 505 or other communication device to communicate information, and processor 510 coupled to bus 505 that may process information. While electronic system 500 is illustrated with a single processor, electronic system 500 may include multiple processors and/or co-processors. Electronic system 500 further may include random access memory (RAM) or other storage device 520 (referred to as memory), coupled to bus 505 and may store information and instructions that may be executed by processor 510.

Memory 520 may also be used to store temporary variables or other intermediate information during execution of instructions by processor 510. In one embodiment, memory 520 may include an array of memory locations that may be accessed using word line decoding techniques as described herein 525. This portion of memory 520 may be, for example, a flash memory device.

Electronic system 500 may also include read only memory (ROM) and/or other static storage device 530 coupled to bus 505 that may store static information and instructions for processor 510. Data storage device 540 may be coupled to bus 505 to store information and instructions. Data storage device 540 such as a magnetic disk or optical disc and corresponding drive may be coupled to electronic system 500.

Electronic system 500 may also be coupled via bus 505 to display device 550, such as a cathode ray tube (CRT) or liquid crystal display (LCD), to display information to a user. Alphanumeric input device 560, including alphanumeric and other keys, may be coupled to bus 505 to communicate information and command selections to processor 510. Another type of user input device is cursor control 570, such as a mouse, a trackball, or cursor direction keys to communicate direction information and command selections to processor 510 and to control cursor movement on display 550.

Electronic system 500 further may include network interface(s) 580 to provide access to a network, such as a local area network. Network interface(s) 580 may include, for example, a wireless network interface having antenna 585, which may represent one or more antenna(e). Network interface(s) 580 may also include, for example, a wired network interface to communicate with remote devices via network cable 587, which may be, for example, an Ethernet cable, a coaxial cable, a fiber optic cable, a serial cable, or a parallel cable.

In one embodiment, network interface(s) 580 may provide access to a local area network, for example, by conforming to IEEE 802.11b and/or IEEE 802.11 g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Associated as well as previous or subsequent versions of the Bluetooth standard may also be supported.

In addition to, or instead of, communication via wireless LAN standards, network interface(s) 580 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

What is claimed is:

1. An apparatus comprising a distributed logical NOR gate to decode addressing signals to generate word line selection signals within a block of memory.

2. The apparatus of claim 1 wherein the distributed logical NOR gate comprises a first transistor coupled with a first set of three transistors coupled with a first word line and a second set of three transistors coupled with a second word line.

3. The apparatus of claim 2 wherein the first transistor comprises a pull-up device coupled with the first set of three transistors and the second set of three transistors.

4. The apparatus of claim 3 wherein the first set of three transistors comprises:
a first p-type transistor having a source coupled with a drain of the pull-up device and a gate coupled to receive a row decode signal;
a first n-type transistor having a drain coupled with the drain of the first p-type transistor and a gate coupled to receive the row decode signal; and
a second n-type transistor having a drain coupled with the drain of the first n-type transistor and a gate coupled with a gate of the pull-up device.

5. The apparatus of claim 4 wherein the second set of three transistors comprises:
a first p-type transistor having a source coupled with a drain of the pull-up device and a gate coupled to receive a row decode signal;
a first n-type transistor having a drain coupled with the drain of the first p-type transistor and a gate coupled to receive the row decode signal; and
a second n-type transistor having a drain coupled with the drain of the first n-type transistor and a gate coupled with a gate of the pull-up device.

6. The apparatus of claim 3 wherein the first transistor, the first set of three transistors, and the second set of three transistors comprise triple-well transistors.

7. A memory device comprising:
a pull-up structure coupled to provide approximately a supply voltage;
a first word line decoder coupled with the pull-up structure having a first p-type transistor with a source coupled with a node of the pull-up structure, a drain coupled with a first output node and a gate coupled to receive a decoded row signal, the first word line decoder further comprising a pair of n-type transistors coupled in parallel with drains coupled with the first output node; and
a second word line decoder coupled with the pull-up structure having a first p-type transistor with a source coupled with the node of the pull-up structure, a drain coupled with a second output node and a gate coupled to receive a decoded row signal, the second word line decoder further comprising a pair of n-type transistors coupled in parallel with drains coupled with the second output node.

8. The memory device of claim 7 wherein the first transistor, the first set of three transistors, and the second set of three transistors comprise triple-well transistors.

9. The memory device of claim 7 wherein the pull-up structure comprises a p-type transistor having a source coupled to receive the supply voltage, a drain coupled with the node of the pull-up structure and a gate coupled with a gate of one of the pair of n-type transistors.

10. The memory device of claim 9 wherein the pull-up structure further comprises a plurality of n-type transistors coupled in series between the gate of the p-type transistor and ground.

11. The memory device of claim 10 wherein the gates of the plurality of n-type transistors are coupled to receive respective address select signals.

12. The memory device of claim 10 wherein the pull-up structure further comprises a second p-type transistor having a drain coupled with the gate of the p-type transistor and a gate coupled to receive a switched biased current control signal.

13. A system comprising:
a substantially omnidirectional antennae;
a processor coupled to communicate via the antennae; and
a memory device coupled with the processor having a distributed logical NOR gate to decode addressing signals to generate word line selection signals within a block of memory.

14. The system of claim 13 wherein the distributed logical NOR gate comprises a first transistor coupled with a first set of three transistors coupled with a first word line and a second set of three transistors coupled with a second word line.

15. The system of claim 14 wherein the first set of three transistors comprises:
a first p-type transistor having a source coupled with a drain of the pull-up device and a gate coupled to receive a row decode signal;
a first n-type transistor having a drain coupled with the drain of the first p-type transistor and a gate coupled to receive the row decode signal; and
a second n-type transistor having a drain coupled with the drain of the first n-type transistor and a gate coupled with a gate of the pull-up device.

16. The system of claim 15 wherein the second set of three transistors comprises:
a first p-type transistor having a source coupled with a drain of the pull-up device and a gate coupled to receive a row decode signal;
a first n-type transistor having a drain coupled with the drain of the first p-type transistor and a gate coupled to receive the row decode signal; and
a second n-type transistor having a drain coupled with the drain of the first n-type transistor and a gate coupled with a gate of the pull-up device.

17. The system of claim 14 wherein the first transistor, the first set of three transistors, and the second set of three transistors comprise triple-well transistors.

18. A system comprising:
a substantially omnidirectional antennae;
a processor coupled to communicate via the antennae; and
a memory device coupled with the processor having a plurality of blocks each having a pull-up structure coupled to provide approximately a supply voltage, a first word line decoder coupled with the pull-up structure having a first p-type transistor with a source coupled with a node of the pull-up structure, a drain coupled with a first output node and a gate coupled to receive a decoded row signal, the first word line decoder further comprising a pair of n-type transistors coupled in parallel with drains coupled with the first output node and a second word line decoder coupled with the pull-up structure having a first p-type transistor with a source coupled with the node of the pull-up structure, a drain coupled with a second output node and a gate coupled to receive a decoded row signal, the second word line decoder further comprising a pair of n-type transistors coupled in parallel with drains coupled with the second output node.

19. The system of claim 18 wherein the first transistor, the first set of three transistors, and the second set of three transistors comprise triple-well transistors.
